(19) United States
(12) Patent Application Publication
(10) Pub. No.: US 2023/0343743 A1
(43) Pub. Date: Oct. 26, 2023

(54) FLIP-CHIP BONDING APPARATUS AND METHOD OF USING THE SAME

(71) Applicant: Taiwan Semiconductor Manufacturing Company, Ltd., Hsinchu (TW)

(72) Inventors: Yi-Jung Chen, Yilan County (TW); Tsung-Fu Tsai, Changhua County (TW); Szu-Wei Lu, Hsinchu City (TW)

(73) Assignee: Taiwan Semiconductor Manufacturing Company, Ltd., Hsinchu (TW)

(21) Appl. No.: 17/726,494

(22) Filed: Apr. 21, 2022

(51) Int. Cl. H01L 23/00

(52) U.S. Cl. CPC H01L 24/80; H01L 24/74; H01L 2224/80006; H01L 2224/80004; H01L 2224/80895; H01L 2224/80896; H01L 2224/80908; H01L 2224/8016; H01L 2224/8017; H01L 2224/8018; H01L 2224/8013; H01L 2224/80123; H01L 2224/80129; H01L 21/563

(57) ABSTRACT

A flip-chip bonding method includes following operations. A wafer is provided with multiple semiconductor dies on an adhesive film held by a frame element. A semiconductor die is lifted up from the wafer by an ejector element. The semiconductor die is picked up with a collector element. The semiconductor die is flip-chipped with the collector element. An alignment check is performed to determine a position of the semiconductor die, so as to determine a process tolerance between a center of the collector element and a center of the semiconductor die. The semiconductor die with the collector element is transferred to a location underneath a bonder element based on the process tolerance of the alignment check. The semiconductor die is picked up from the collector element by the bonder element. The semiconductor die is bonded to a carrier by the bonder element.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. During the integration, the transportation of the devices and components has been developed.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1E are simplified perspective views showing different stages of a semiconductor die in a flip-chip bonding apparatus in accordance with some embodiments of the disclosure.

FIG. 2 through FIG. 10 are schematic cross-sectional views showing a method of using a flip-chip bonding apparatus during manufacturing a semiconductor device in accordance with some embodiments of the disclosure.

FIG. 11 illustrates a method of forming a semiconductor device in accordance with some embodiments of the disclosure.

FIG. 12 illustrates a method of forming a semiconductor device in accordance with some embodiments of the disclosure.

FIG. 13 illustrates a method of forming a semiconductor device in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third” and the like, may be used herein for ease of description to describe similar or different element(s) or feature(s) as illustrated in the figures, and may be used interchangeably depending on the order of the presence or the contexts of the description.

It should be appreciated that the following embodiment(s) of the disclosure provides applicable concepts that can be embodied in a wide variety of specific contexts. The specific embodiment(s) discussed herein is merely illustrative and is related to a flip-chip bonding apparatus and its using method during a manufacture of a semiconductor device, such as a semiconductor package or a semiconductor die (e.g., a system-on-integrated circuit (SoIC), or the like). In some embodiments, a flip-chip bonding apparatus includes an optical microscope (e.g., IC camera) for an alignment check before the semiconductor die is transferred to a bonder element. Such alignment check provides overlay data to compensate the die shift, so that the semiconductor die can be bonded to the bonder element accurately and therefore bonded to the carrier precisely.

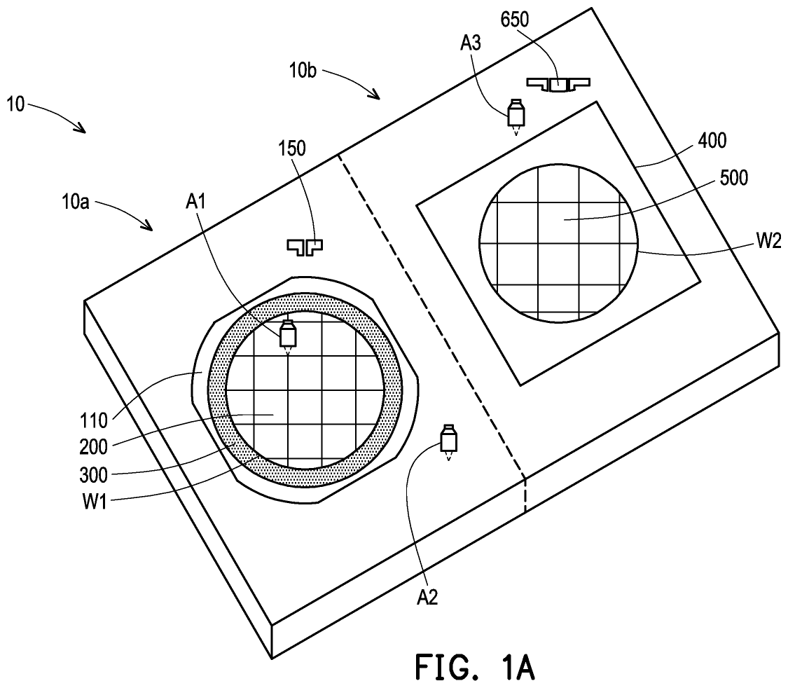

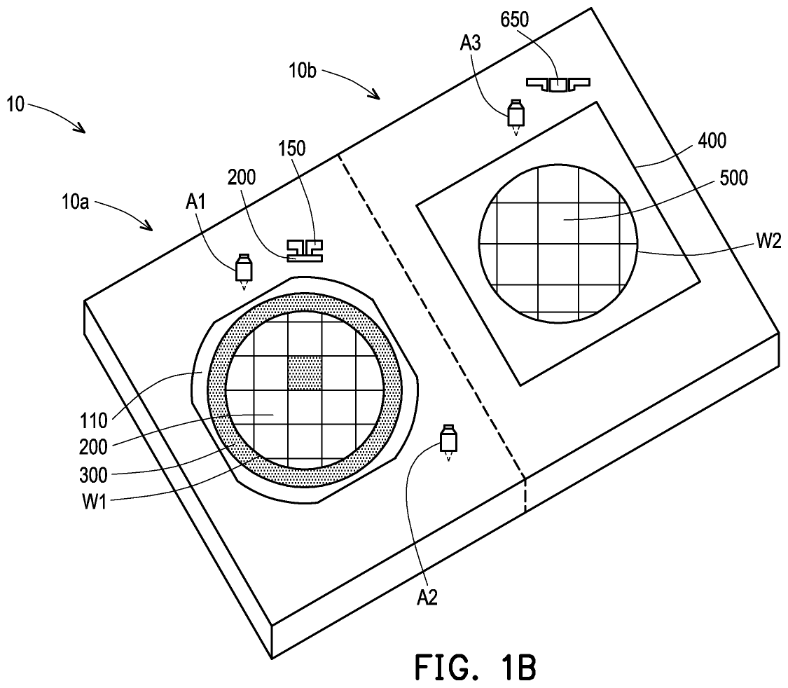

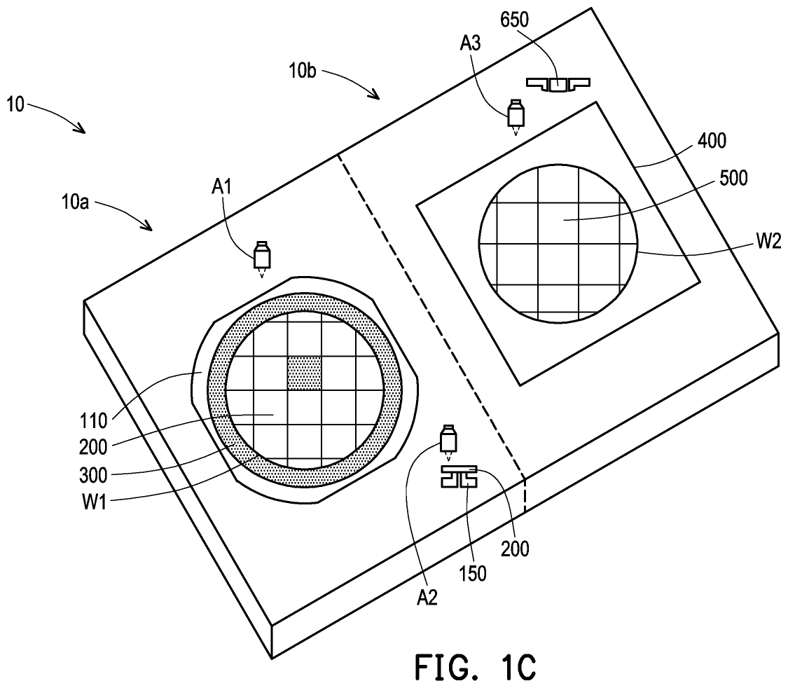

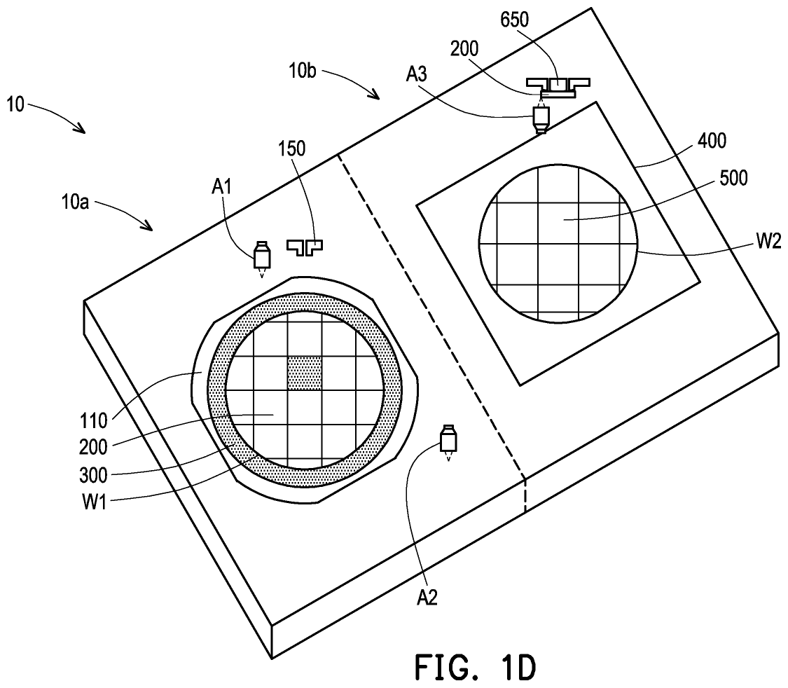

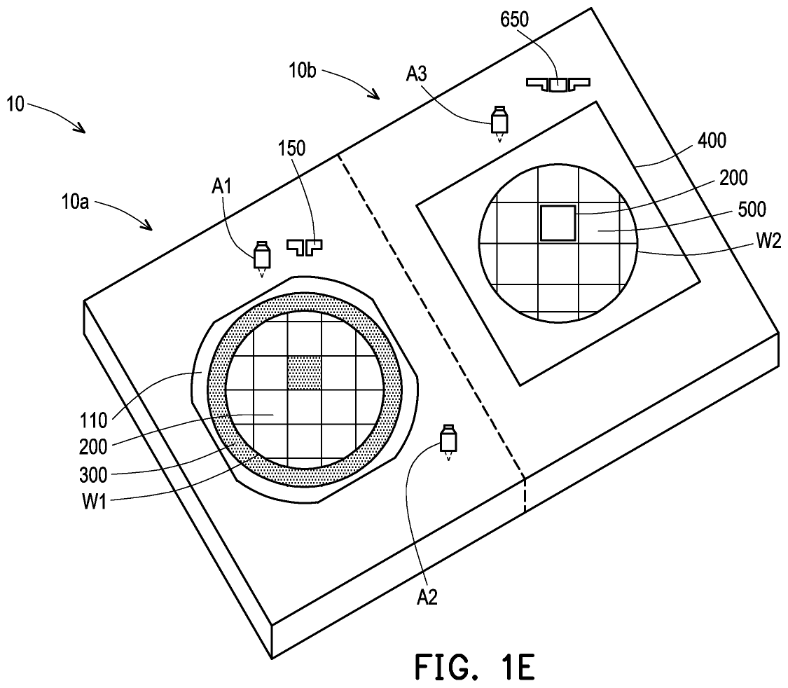

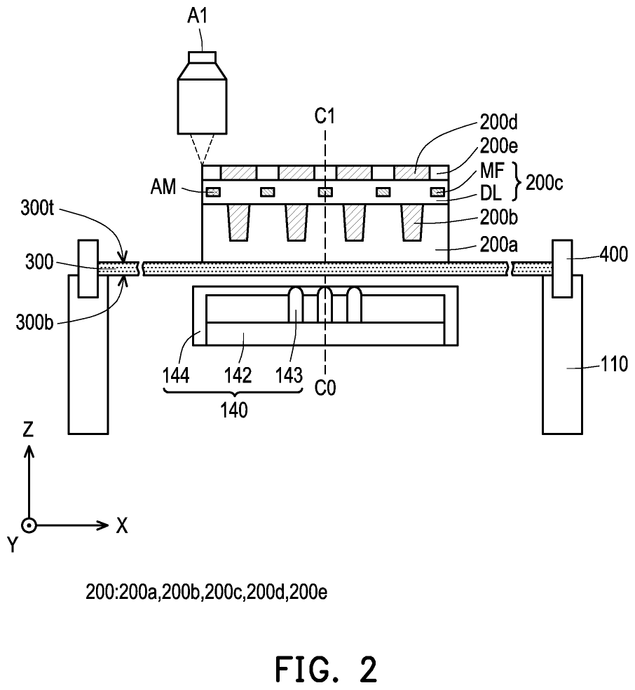

FIG. 1A to FIG. 1E are simplified perspective views showing different stages of a semiconductor die 200 in a flip-chip bonding apparatus 10 in accordance with some embodiments of the disclosure, in which merely some elements or components are illustrated for the purpose of simplicity and clarity. It is understood that the disclosure is not limited by the flip-chip bonding apparatus shown in FIG. 1A to FIG. 1E. Other elements or components (such as an ejector element, etc.) may be show in other cross-sectional views (such as FIG. 2). Additional elements or components (such as mechanical arms, motors, controllers, etc.) can be provided within or outside of the apparatus, and the described elements or components can be replaced or modified for other embodiments.

Referring to FIG. 1A to FIG. 1E, a flip-chip bonding apparatus 10 is provided to perform a die lift-up operation (as shown in FIG. 1A), a die pick-up operation (as shown in FIG. 1B), a flip-chip operation (as shown in FIG. 1C), a die transfer operation (as shown in FIG. 1D), and a die bonding operation (as shown in FIG. 1E). In some embodiments, the flip-chip bonding apparatus 10 includes a pick-up unit 10a and a bonding unit 10b adjacent to each other. A semiconductor die 200 is picked up by a collector element 150 from a wafer W1 (as shown in FIG. 1A to FIG. 1B) and then flip-chipped by the collector element 150 (as shown in FIG. 1C) in the pick-up unit 10a. Thereafter, the flip-chipped semiconductor die 200 is transferred from the collector element 150 to a bonder element 650 (as shown in FIG. 1D) and then bonded to the carrier W2 (as shown in FIG. 1E) in the bonding unit 10b. The relationships between elements and the functions of the elements will be described in details below.

In some embodiments, in the flip-chip bonding apparatus 10, the pick-up unit 10a includes a frame element 110, an ejector element 140 (as shown in FIG. 2), a first optical microscope A1, a collector element 150 and a second optical microscope A2. The frame element 110 is configured to hold an adhesive film 300 adhered with a wafer W1 having multiple semiconductor dies 200. The ejector element 140 (as shown in FIG. 2) is configured to lift up a semiconductor die 200 selected from the semiconductor dies 200 of the wafer W1. The first optical microscope A1 is configured to check a position of the semiconductor die 200, so as to determine the process tolerance between the semiconductor die 200 and the ejector element 140 before the die lifting up operation. The collector element 150 is dispose over the frame element 110 and configured to pick up the semiconductor die 200, as shown in FIG. 1A. The second optical microscope A2 is configured to check a position of the semiconductor die 200, so as to determine the process tolerance between the semiconductor die 200 and the collector element 150 after the flip chip operation, as shown in FIG. 1B.

In some embodiments, the bonding region 10b incudes a stage 400, a bonding element 650 and a third optical microscope A3. The stage 400 is configured to hold a carrier W2. The bonding element 650 is disposed over the stage 400 and configured to receive the semiconductor die 200 from the collector element 150, as shown in FIG. 1C. The third optical microscope A3 is configured to check a position of the semiconductor die 200, so as to determine the process tolerance between the semiconductor die 200 and the carrier W2.

In some embodiments, one or more than one optical microscope is integrated in the collector element 150 or one or more than one optical microscope is installed onto the moving mechanism next to the collector element 150. In some embodiments, one or more than one optical microscope is integrated in the bonder element 650 or one or more than one optical microscope is installed onto the moving mechanism next to the bonder element 650.

In some embodiments, three optical microscopes A1, A2 and A3 are included within the flip-chip bonding apparatus 10 to ensure an accurate die-to-carrier bonding process. Specifically, an optical microscope A1 is provided in the pick-up unit 10a for checking the position of the selected die before the die lifting operation, and an optical microscope A3 is provided in the bonding unit 10b for checking the position of the selected die before the bonding operation. In some embodiments, an optical microscope A2 is further provided for checking the position of the selected die before the die transferring operation, and such alignment check is helpful because it can compensate the die shift during the die lift and pickup operation, which will be described in details below.

In some embodiments, the flip-chip bonding apparatus 10 shown in FIG. 1A to FIG. 1E is provided to manufacture a semiconductor device, such as a semiconductor package or a semiconductor die (e.g., a system-on-integrated circuit (SoIC), or the like). However, the present disclosure is not limited thereto. The flip-chip bonding apparatus 10 shown in FIG. 1A to FIG. 1E can be applied to other semiconductor devices in other embodiments.

FIG. 2 through FIG. 10 are schematic cross-sectional views showing a method of using a flip-chip bonding apparatus during manufacturing a semiconductor device in accordance with some embodiments of the disclosure. It is understood that the disclosure is not limited by the method described below. Additional operations can be provided before, during, and/or after the method and some of the operations described below can be replaced or eliminated, for additional embodiments of the methods.

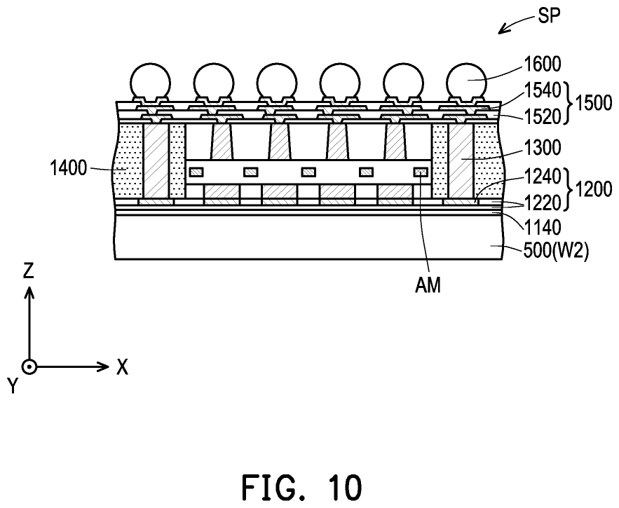

Referring to FIG. 2, in some embodiments, a method of using a flip-chip bonding apparatus 10 during the manufacturing process of a semiconductor package SP (as shown in FIG. 10) includes following operations. First, a wafer W1 (as shown in FIG. 1A) including semiconductor dies 200 is provided over a frame element 110, and a dicing process is performed to cut the wafer W1 into individual and separated semiconductor dies 200 along cutting lines. In one embodiment, the dicing process is a wafer dicing process including mechanical blade sawing or laser cutting. In some embodiments, before dicing/singulating, the semiconductor dies 200 included in the wafer W1 are tested for functionality and performance by probing, and only known good dies (KGDs) from the tested semiconductor dies 200 are selected and used for subsequently processing. In some embodiments, the known good dies (KGDs) from the tested semiconductor dies 200 are placed onto and adhered to an adhesive film 300 for subsequently processing. FIG. 2 illustrates only one semiconductor die 200 on the adhesive film 300 for illustrative purposes and for simplicity, but the disclosure is not limited thereto. The adhesive film 300 is a continuous film, in some embodiments. The adhesive film 300 may be referred to as a frame tape or tape in some examples.

In addition, the semiconductor dies 200 may be arranged in an array in the wafer W1. In some embodiments, the semiconductor dies 200 are arranged in the form of a matrix, such as a N×N array or a N×M array (N, M>0, N may or may not be equal to M) along a direction X and a direction Y. The direction X and the direction Y are not the same to each other and are perpendicular to each other, for example.

As shown in FIG. 2, the semiconductor die 200 may be referred to as a semiconductor die or chip including a digital chip, analog chip or mixed signal chip. In some embodiments, the semiconductor die 200 is a logic die, a memory die, a CPU, a GPU, an xPU, a MEMS die, a SoC die, or the like.

In some embodiments, the semiconductor die 200 includes a substrate 200a, through substrate vias 200b, an interconnect structure 200c, connectors 200d and a passivation layer 200e. The substrate 200a is a silicon substrate. The substrate 200a has a transistor (not shown) formed thereon, and the interconnect structure 200c is formed over the substrate 200a and electrically connected to the transistor. In some embodiments, the substrate 200a has through substrate vias 200b (also called “through silicon vias” in some examples) formed therein, and the through substrate vias 200b are not revealed from the back surface of the substrate 200a at this stage. The interconnect structure 200b includes dielectric layers DL and metal features MF embedded by the dielectric layers DL. The metal features include metal lines, metal vias, metal pads and/or metal connectors. In some embodiments, each metal feature MF includes Cu, Al, Ti, Ta, W, Ru, Co, Ni, the like, or a combination thereof. In some embodiments, each dielectric layer DL includes silicon oxide, silicon nitride, silicon oxynitirde, SiOC, the like, or a combination thereof. An etching stop layer may be interposed between two adjacent dielectric layers. The dielectric layers of the interconnect structure 200b may be replaced by polymer layers or insulating layers in other embodiments. The connectors 200d are metal pillars (e.g., copper pillars). The metal pillars include Cu, W, Ni, Sn, Ti, Au, an alloy or a combination thereof, and are formed by an electroplating process. The passivation layer 200e is formed around the connectors 200d. The passivation layer 200e includes a polymer material such as polybenzoxazole (PBO), polyimide, benzocyclobutene (BCB), the like, or a combination thereof. In some embodiments, the top surfaces of the connectors 200d are flushed with the top surface of the passivation layer 200e. In some embodiments, at least one alignment mark AM is formed on or in the semiconductor die 200. In some embodiments, the alignment mark AM is formed during the metal features MF are formed in the interconnect structure 200c. The alignment mark AM is square, rectangular, polygonal, strip-shaped, T-shaped, L-shaped, box-shaped, cross-shaped or any suitable shape. In some embodiments, the alignment mark is optional and may be omitted in other embodiments.

Continued to FIG. 2, in some embodiment, the semiconductor die 200 adhered to the adhesive film 300 is placed onto the flip-chip bonding apparatus 10. The adhesive film 300 may be fixed onto the flip-chip bonding apparatus 10 through a loading element 400, where the loading element 400 may be disposed in or on the frame element 110. As shown in FIG. 2, for example, the adhesive film 300 is installed onto the flip-chip bonding apparatus 10 through at least partially inserting the loading element 400 into the frame element 110, where an edge of the adhesive film 300 is clamped by the loading element 400. The loading element 400 may include a fastener such as a bolt, a flange ring, or the like. In some embodiments, the loading element 400 is further capable of moving the adhesive film 300 so to align a to-be-picked up semiconductor die 200 with the ejector element 140 along a stacking direction Z.

As shown in FIG. 2, the semiconductor die 200 is disposed on (e.g., in physical contact with) a top surface 300t of the adhesive film 300, and a bottom surface 300b of the adhesive film 300 props against (e.g., in physical contact with) a top surface of the frame element 110. The material of the frame element 110 may include a dielectric material, a conductive material or a combination of. For example, the frame element 110 is made of a metallic material (such as a metal or a metal alloy).

The frame element 110 may stand on a base or stage (not shown), such that an accommodating space may be confined for accommodating the ejector element 140. For example, the ejector element 140 is disposed inside the frame element 110. In other words, the ejector element 140 is under the adhesive film 300, as shown in FIG. 2, for example.

In some embodiments, the ejector element 140 includes a pin chuck 142, pins 143 and a housing 144, where the pin chuck 142 and the pins 143 are disposed inside the housing 144, as shown in FIG. 2. In some embodiments, the pins 143 are disposed on the pin chuck 142 and completely embedded in the housing 144. However, the disclosure is not limited thereto. In other embodiments, the pins 143 are disposed on the pin chuck 142 and partially embedded in the housing 144. A motor (not shown) is configured to move up and down the pins 143 in respective with the top surface of the housing 144, so as to control movements of the pins 143 in other embodiments during the manufacture of the semiconductor package SP. The pins 143 may be referred to as lifting pins or pick-up pins in some examples.

In some embodiments, materials of the pin chuck 142, the pins 143 and the housing 144 independently include a metallic material, such as metal or metal alloy. For example, the pin chuck 142, the pins 143 and the housing 144 independently may be made of iron (Fe), chromium (Cr), nickel (Ni), Aluminum (Al), stainless steel, combinations thereof, or the like. The materials of the pin chuck 142, the pins 143, and the housing 144 may be the same. The disclosure is not limited thereto; alternatively, the materials of the pin chuck 142, the pins 143, and the housing 144 may be different, in part or all.

In some embodiments, the ejector element 140 is positioned under the semiconductor die 200. The center C0 of the ejector element 140 is substantially aligned with the center C1 of the semiconductor die 200 along the stacking direction Z, for example. In some embodiments, the flip-chip bonding apparatus 10 further includes a moving mechanism, where the ejector element 140 is connected to a moving mechanism (not shown) to control the movement of the ejector element 140. For example, the moving mechanism is configured to move the ejector element 140 vertically along the direction Z and/or horizontally along the direction X and/or Y. The moving mechanism may include a mechanical arm or the like.

Still referring to FIG. 2, an alignment check is performed by an optical microscope A1 to determine a position of the semiconductor die 200 so as to determine whether the center C1 of the semiconductor die 200 selected from the wafer W1 is aligned with the center C0 of the ejector element 140. In some embodiments, the alignment check includes detection of an intensity of light reflection of the alignment mark AM on the semiconductor die 200 by an optical microscope. In some embodiments, the alignment check includes detection of an edge or border of the semiconductor die 200 by a camera. The edge or border of the semiconductor die 200 functions as the alignment mark for the semiconductor die 200.

In some embodiments, the position of the frame element 110 or the ejector element 140 is adjusted if the result of the alignment check of FIG. 2 shows a misalignment between the center C0 of the collector element 140 and the center C1 of the semiconductor die 200. The frame element 110 is connected to a moving mechanism (not shown) to control the movement of the frame element. For example, the moving mechanism is configured to move the frame element 110 vertically along the direction Z and/or horizontally along the direction X and/or Y. The moving mechanism may include a mechanical arm or the like.

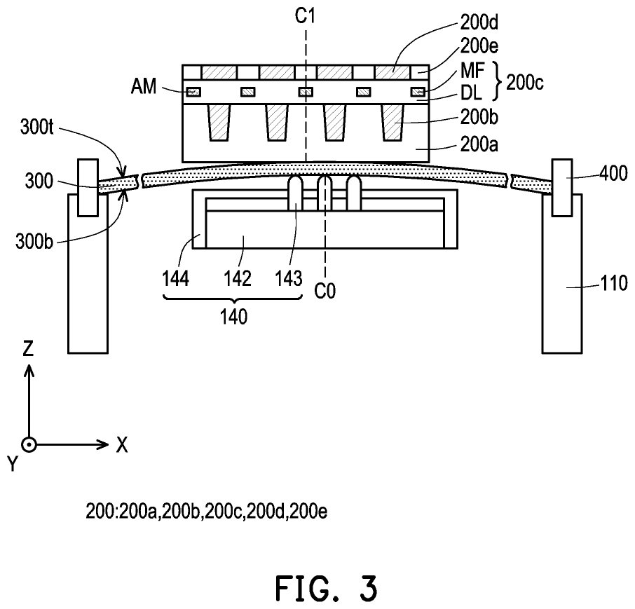

Referring to FIG. 3, after the alignment check of FIG. 2, the semiconductor die 200 is lifted up from the wafer W1 by the ejector element 140. In some embodiments, the lifting pins 143 move upwards to push up the semiconductor die 200. However, during the die lifting operation, a slight die shift may occur. The slight die shift may be caused by a bending of the adhesive film 300 or a slight warpage profile of the semiconductor die itself. In some embodiments, upon the die lifting operation, the center C0 of the ejector element 140 is misaligned with the center C 1 of the semiconductor die 200 along the stacking direction Z, as shown in FIG. 3.

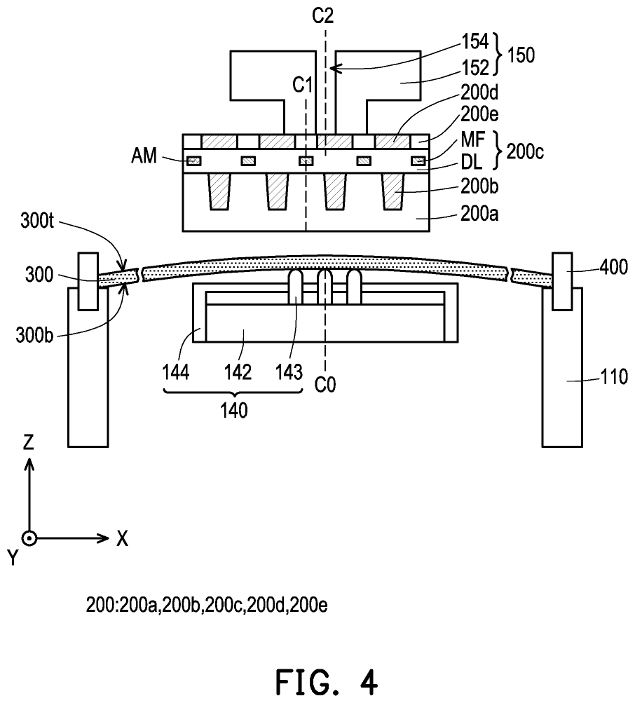

Referring to FIG. 4, a collector element 150 is provided above the semiconductor die 200. In some embodiments, due to the die shift, the center C1 of the semiconductor die 200 is misaligned with the center C0 of the ejector element 140 or the center C2 of the collector element 150 along the stacking direction Z. For example, the center C0 of the ejector element 140 and the center C2 of the collector element 150 may be substantially aligned with each other along the stacking direction Z, but the center C1 of the semiconductor die 200 is shifted from the center C0 of the ejector element 140 and the center C2 of the collector element 150.

In some embodiments, the collector element 150 includes a body 152, at least one channel 154 embedded therein, and a vacuum element (not shown) connected to the channel 154, as shown in FIG. 4. In some embodiments, only one channel 154 penetrates through the body 152. However, the disclosure is not limited thereto. In other embodiments, multiple channels penetrate through the body 152 in other embodiments. For example, the vacuum element is configured to provide a vacuum force (e.g., generating a negative pressure) to the channel 154 for picking up the semiconductor die 200. The channel 154 may be referred to as a vacuum path or a vacuum channel.

In some embodiments, a material of the body 152 includes a metallic material, such as metal or metal alloy. The material of the body 152 may be the same as the materials of the pin chuck 142, the pins 143, and the housing 144. The disclosure is not limited thereto; alternatively, the material of the body 152 may be different from the materials of the pin chuck 142, the pins 143, and the housing 144, in part or all.

Still referring to FIG. 4, the semiconductor die 200 is removed (e.g., picked up) from the adhesive film 300 by the collector element 150. For example, the collector element 150 is moved down along the direction Z until the surface of the collector element 150 is in (physical) contact with the front-side surface of the semiconductor die 200, and the collector element 150 applies a vacuum force on the semiconductor die 200 through the channel 154, such that the semiconductor die 200 is held by the collector element 150 by a suction force, as shown in FIG. 4. As the semiconductor die 200 is held by the collector element 150, there is a direct contact therebetween. The collector element 150 may be referred to as a contact mode collector. However, the disclosure is not limited thereto. In other embodiments, a contactless mode collector element may be applied in other embodiments.

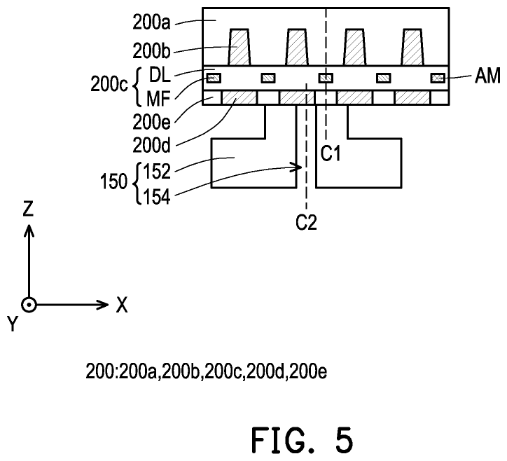

Referring to FIG. 5, the semiconductor die 200 with the collector element 150 is flip-chipped. In some embodiments, the collector element 150 and the semiconductor die 200 held therefrom are flipped (turned upside down). The back-side surface of the semiconductor die 200 is then facing up, for example.

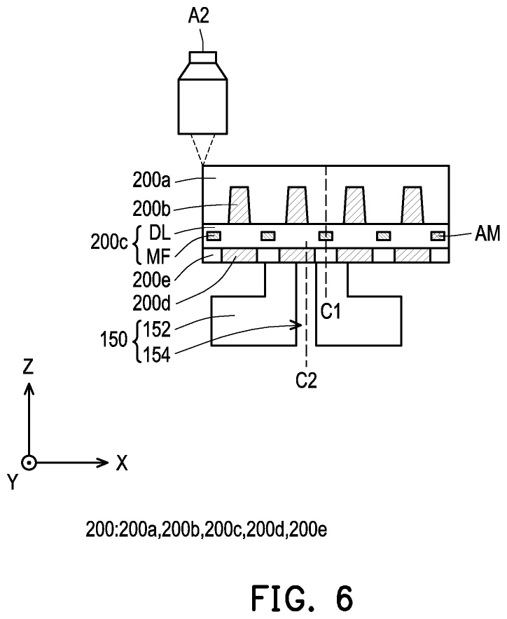

Referring to FIG. 6, an alignment check is performed by an optical microscope A2 to determine a position of the semiconductor die 200 so as to determine whether the center C1 of the semiconductor die 200 is aligned with the center C2 of the collector element 150. In some embodiments, the alignment check includes detection of an intensity of light reflection of the alignment mark AM on the semiconductor die 200 by an optical microscope. In some embodiments, the alignment check includes detection of an edge or border of the semiconductor die 200 by a camera. The edge or border of the semiconductor die 200 functions as the alignment mark for the semiconductor die 200.

In some embodiments, the flip-chip bonding apparatus 10 further includes a moving mechanism, where the collector element 150 is connected to the moving mechanism (not shown) to control the movement of the collector element 150. For example, the moving mechanism is configured to move the collector element 150 vertically along the direction Z and/or horizontally along the direction X and/or Y. The moving mechanism may include a mechanical arm or the like.

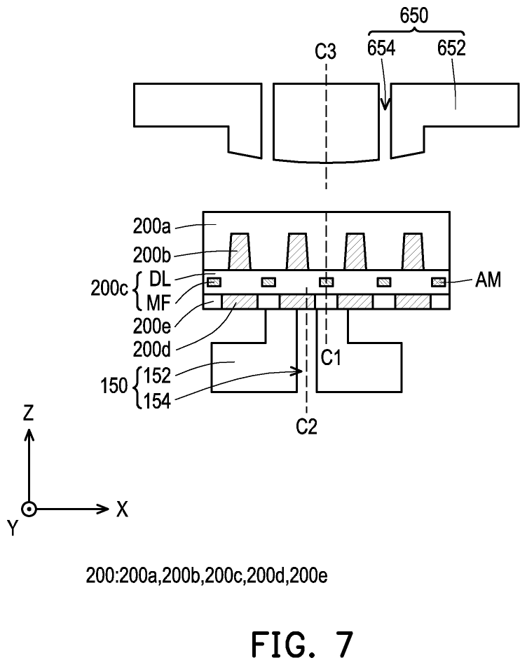

Referring to FIG. 7, after the alignment check of FIG. 6, a bonder element 650 is provided and placed over the semiconductor die 200 for picking the semiconductor die 200 from the collector element 150. In some embodiments, the semiconductor die 200 with the collector element 150 is transferred to a location underneath a bonder element 650 based on the result of the alignment check of FIG. 6. Specifically, the semiconductor die 200 with the collector element 150 is transferred to a position where the center C3 of the bonder element 650 is substantially aligned with the center C1 of the semiconductor die 200. In other words, the transferring operation compensates the die shift during the die lift and pickup operation.

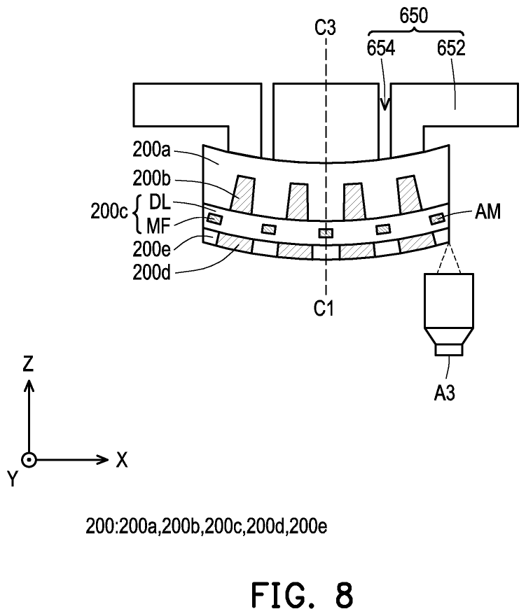

In some embodiments, the bonder element 650 includes a body 652, at least one channel 654 embedded therein, and a vacuum element (not shown) connected to the channel 654, as shown in FIG. 7. In some embodiments, multiple channels 654 (such as two channels) penetrate through the body 652. However, the disclosure is not limited thereto. In other embodiments, only one channel penetrates through the body 652. For example, the vacuum element is configured to provide a vacuum force (e.g., generating a negative pressure) to the channels 654 for picking up the semiconductor die 200. The channels 654 may be referred to as vacuum paths or a vacuum channels. In some embodiments, the bonder element 650 has a curved surface facing to the semiconductor die 200, as shown in FIG. 8. Such curved surface is beneficial to pick up a semiconductor die 200 with a slight warpage profile in some examples. However, the disclosure is not limited thereto. In other embodiments, the bonder element 650 has a flat surface facing to the semiconductor die 200.

In some embodiments, a material of the body 652 includes a metallic material, such as metal or metal alloy. The material of the body 652 may be the same as the material of the material of the body 152. The disclosure is not limited thereto; alternatively, the material of the body 652 may be different from the material of the body 152.

Referring to FIG. 7 and FIG. 8 together, the semiconductor die 200 is transferred from the collector element 150 to the bonder element 650. In some embodiments the surface of the bonder element 650 is in contact with the back-side surface of the semiconductor die 200, and the bonder element 650 applies a vacuum force on the semiconductor die 200 through the channel 654, such that the semiconductor die 200 is held by the bonder element 650 by direct contact. In some embodiments, after the semiconductor die 200 is securely held by the bonder element 650 in an accurate position, the semiconductor die 200 is released by the collector element 150. The bonder element 650 may be referred to as a bonder head in some examples.

In some embodiments, the flip-chip bonding apparatus 10 further includes a moving mechanism, where the bonder element 650 is connected to the moving mechanism (not shown) to control the movement of the bonder element 650. For example, the moving mechanism is configured to move the bonder element 650 vertically along the direction Z and/or horizontally along the direction X and/or Y. The moving mechanism may include a mechanical arm or the like.

In some embodiments, during the transferring operation, the position of at least one of the collector element 150 and the bonder element 650 is adjusted based on the feedback of the alignment check of FIG. 6, until the center C3 of the bonder element 650 is substantially aligned with the center C1 of the semiconductor die 200.

Still referring to FIG. 8, an alignment check is performed by an optical microscope A3 to determine a position of the semiconductor die 200 so as to determine whether the center C1 of the semiconductor die 200 is aligned with the center C2 of the collector element 150 or the center of the subsequently bonded region (e.g., desired region 500 of the carrier W2). In some embodiments, the alignment check includes detection of an intensity of light reflection of the alignment mark AM on the semiconductor die 200 by an optical microscope. In some embodiments, the alignment check includes detection of an edge or border of the semiconductor die 200 by a camera. The edge or border of the semiconductor die 200 functions as the alignment mark for the semiconductor die 200.

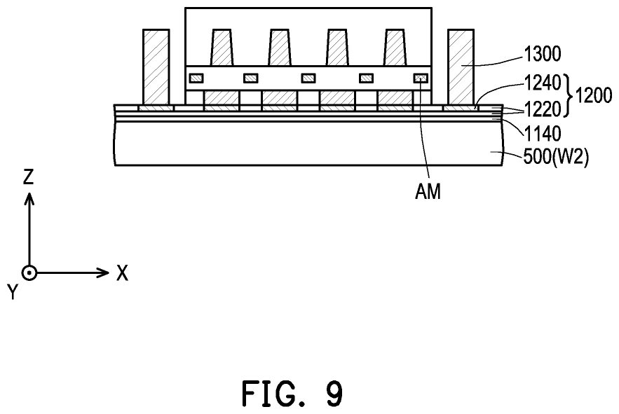

Referring to FIG. 9, a carrier W2 is provided. In some embodiments, the carrier W2 includes multiple desired regions 500 for semiconductor dies 200 to bond thereon, respectively, as shown in FIG. 1C.

In one embodiment, the carrier W2 may be a glass carrier or any suitable carrier for carrying a semiconductor wafer or a reconstituted wafer for the manufacturing method of the semiconductor package. In another embodiment, the carrier W2 may be a reclaim wafer or a reconstituted wafer for the manufacturing method of the semiconductor package. For example, as the material of the carrier W2 is a silicon substrate, the carrier W2 may serve as a heat dissipating element for the semiconductor package SP. In such embodiments, the carrier W2 may further be used for warpage control. In some other embodiments of which the carrier W2 is removed after the manufacture of the semiconductor package, the carrier W2 may further be coated with a debond layer 1140. For example, the debond layer 1140 is disposed on the carrier W2, and the material of the debond layer 1140 may be any material suitable for bonding and debonding the carrier W2 from the above layer(s) (e.g., the buffer layer) or any wafer(s) disposed thereon. In some embodiments, the debond layer 1140 may include a release layer (such as a light-to-heat conversion (“LTHC”) layer) or an adhesive layer (such as an ultra-violet curable adhesive or a heat curable adhesive layer).

In some embodiments, the position of the carrier W2 or the bonder element 650 is adjusted if the result of the alignment check of FIG. 8 shows a misalignment between the center C3 of the bonder element 650 and the center C1 of the semiconductor die 200. The carrier W2 is connected to a moving mechanism (not shown) to control the movement of the carrier W2. For example, the moving mechanism is configured to move the carrier W2 vertically along the direction Z and/or horizontally along the direction X and/or Y. The moving mechanism may include a mechanical arm or the like.

In some embodiments, a redistribution circuit structure 1200 is formed on the carrier W2. The redistribution circuit structure 1200 may include one or more metallization patterns 1240 embedded in one or more polymer layers 1220. In some embodiments, the material of the polymer layers 1220 may include polyimide, epoxy resin, acrylic resin, phenol resin, benzocyclobutene (BCB), polybenzoxazole (PBO), or any other suitable polymer-based dielectric material, and the polymer layers 1220 may be formed by deposition. In some embodiments, the material of the metallization patterns 1240 may include aluminum, titanium, copper, nickel, tungsten, and/or alloys thereof, and the metallization patterns 1240 may be formed by electroplating or deposition.

In some embodiments, as shown in FIG. 9, through dielectric vias 1300 are formed on the redistribution circuit structure 1200. For example, the through dielectric vias 1300 are physically connected to the portions of the metallization patterns 1240 exposed by the topmost polymer layer 1220. In other words, the through dielectric vias 1300 are electrically connected to the redistribution circuit structure 1200. The through dielectric vias 1300 are referred to as through integrated fan-out (InFO) vias in some examples. In some embodiments, the through dielectric vias 1300 are formed by photolithography, plating, photoresist stripping processes or any other suitable method. In one embodiment, the material of the through dielectric vias 1300 may include a metal material such as copper or copper alloys, or the like.

Continue referring to FIG. 9, after the alignment check of FIG. 8, the semiconductor die 200 is bonded to the carrier W2 by the bonder element 650. In some embodiments, as shown in FIG. 9, the semiconductor die 200 is placed on the redistribution circuit structure 1200 by the bonder element 650. After the placing, the semiconductor die 200 may be released from the bonder element 650.

In some embodiments, a bonding interface between the semiconductor die 200 and the redistribution circuit structure 1200 includes metal-to-metal bonding (e.g., copper-to-copper bonding) and dielectric-to-dielectric bonding (e.g., oxide-to-oxide bonding, oxide-to-nitride bonding, or nitride-to-nitride bonding). That is, the bonding process includes a hybrid bonding process, for example. In some embodiments, the connectors 200d of the semiconductor die 200 and the metallization patterns 1240 of the redistribution circuit structure 1200 are bonded together through a direct metal-to-metal bonding, and the passivation layer 200e of the semiconductor die 200 and the topmost polymer layer 1220 of the redistribution circuit structure 1200 are bonded together through a direct dielectric-to-dielectric bonding. In the disclosure, the bonding interface may be referred to as a hybrid bonding interface. In other words, the semiconductor die 200 is electrically connected to the redistribution circuit structure 1200, and at least some of the through dielectric vias 1300 are electrically connected to the semiconductor die 200 through the redistribution circuit structure 1200. The redistribution circuit structure 1200 may be referred to as a front-side redistribution layer of the semiconductor die 200.

Referring to FIG. 10, the semiconductor die 200 and the through dielectric vias 1300 are encapsulated in a dielectric encapsulation 1400, and a redistribution circuit structure 1500 and conductive terminals 1600 are sequentially formed on the dielectric encapsulation 1400. In some embodiments, the redistribution circuit structure 1500 is electrically connected to the semiconductor die 200 through the through dielectric vias 1300 and the redistribution circuit structure 1200. In some embodiments, some of the conductive terminals 1600 are electrically connected to the semiconductor die 200 through the redistribution circuit structure 1500, the through dielectric vias 1300 and the redistribution circuit structure 1200.

The method of forming the dielectric encapsulation 1400 may include forming a dielectric encapsulation material over the carrier W2 (e.g., on the redistribution circuit structure 1200), and then planarizing the dielectric encapsulation material until surfaces of the through substrate vias 200b of the semiconductor die 200 and surfaces of through dielectric vias 1300 are exposed. In some embodiments, the dielectric encapsulation 1400 is a molding compound formed by a molding process, and the material of the dielectric encapsulation 1400 may include epoxy or other suitable resins. For example, the dielectric encapsulation 1400 may be epoxy resin containing chemical filler.

The redistribution circuit structure 1500 may include polymer layers 1520 and metallization patterns 1540 stacked alternately. The formation and material of the polymer layers 1520 may be identical or similar to the formation and material of the polymer layers 1220 as described in FIG. 9, and the formation and material of the metallization patterns 1540 may be identical or similar to the formation and material of the metallization patterns 1240 as described in FIG. 9, and thus are not repeated herein for brevity. In certain embodiments, the topmost metallization pattern 1540 may serve as under-ball metallurgy (UBM) pads for ball mount. In some embodiments, the redistribution circuit structure 1500 may be referred to as a back-side redistribution layer of the semiconductor die 200.

In some embodiments, the conductive terminals 1600 may be placed on the UBM pads through ball placement process and/or reflow process, or other suitable forming method. In some embodiments, the conductive terminals 1600 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The material of the conductive terminals 1600, for example, may include a conductive material such as solder, copper, aluminum, gold, nickel, silver, palladium, tin, or the like, or a combination thereof. In one embodiment, the material of the conductive terminals 1600, for example, may be solder-free.

After the formation of the conductive terminals 1600, in some embodiments, a dicing process is performed to cut through the redistribution circuit structure 1500, the dielectric encapsulation 1400 and the redistribution circuit structure 1200 to obtain individual and separated semiconductor packages SP. In one embodiment, the dicing process is a wafer dicing process including mechanical blade sawing or laser cutting. The manufacture of the semiconductor package SP is thus completed. In some embodiments, after the dicing process, the carrier W2 may be detached from the redistribution circuit structure 1200 through a debonding process, where the carrier W2 and the debond layer 1140 may be removed and the redistribution circuit structure 1200 may be exposed. The semiconductor package SP may be referred to as an InFO package.

The semiconductor package SP may be further mounted with a circuit substrate, an interposer, an additional package, chips/dies or other electronic devices to form a stacked package structure through the conductive terminals 1600 and/or other additional connectors based on the design layout and the demand.

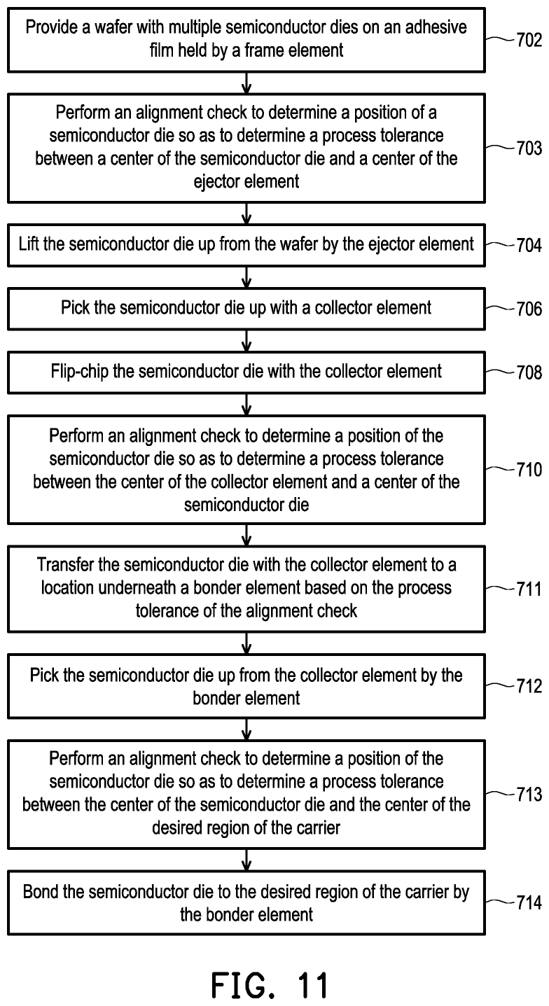

FIG. 11 illustrates a method of forming a semiconductor device in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 702, a wafer is provided with multiple semiconductor dies on an adhesive film held by a frame element. FIG. 1A and FIG. 2 illustrate different views corresponding to some embodiments of act 702.

At act 703, an alignment check is performed to determine a position of a semiconductor die so as to determine a process tolerance between a center of the semiconductor die and a center of the ejector element. FIG. 1A and FIG. 2 illustrate different views corresponding to some embodiments of act 703.

At act 704, the semiconductor die is lifted up from the wafer by the ejector element. FIG. 3 illustrates a cross-sectional view corresponding to some embodiments of act 704.

At act 706, the semiconductor die is picked up with a collector element. FIG. 1B and FIG. 4 illustrate different views corresponding to some embodiments of act 706.

At act 708, the semiconductor die with the collector element is flip-chipped. FIG. 1C and FIG. 5 illustrate different views corresponding to some embodiments of act 708.

At act 710, an alignment check is performed to determine a position of the semiconductor die so as to determine a process tolerance between the center of the collector element and a center of the semiconductor die. FIG. 1C and FIG. 6 illustrate different views corresponding to some embodiments of act 710.

At act 711, the semiconductor die with the collector element is transferred to a location underneath a bonder element based on the process tolerance of the alignment check at act 710. In some embodiments, the transferring process is optimized until a center of the bonder element is substantially aligned with the center of the semiconductor die. FIG. 1C, FIG. 1D and FIG. 7 illustrate different views corresponding to some embodiments of act 711.

At act 712, the semiconductor die is picked up from the collector element by the bonder element. FIG. 1D and FIG. 8 illustrate different views corresponding to some embodiments of act 712.

At act 713, an alignment check is performed to determine a position of the semiconductor die so as to determine a process tolerance between the center of the semiconductor die and the center of the desired region of the carrier. FIG. 8 illustrates a cross-sectional view corresponding to some embodiments of act 713.

At act 714, the semiconductor die is bonded to the desired region of the carrier by the bonder element. FIG. 1E and FIG. 9 to FIG. 10 illustrate different views corresponding to some embodiments of act 714.

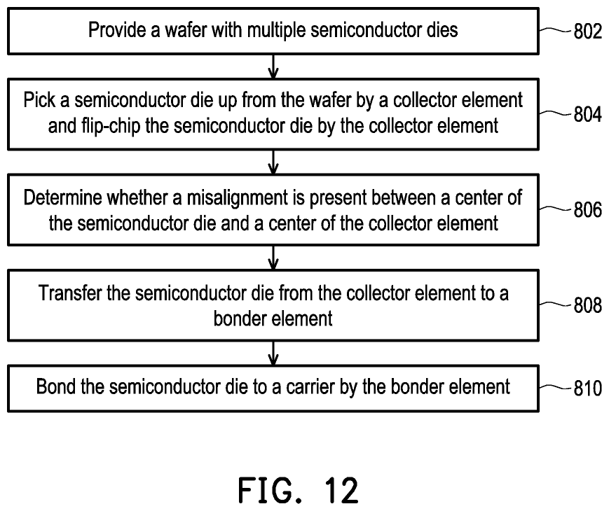

FIG. 12 illustrates a method of forming a semiconductor device in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 802, a wafer is provided with multiple semiconductor dies. FIG. 1A and FIG. 2 illustrate different views corresponding to some embodiments of act 802.

At act 804, a semiconductor die is picked up from the wafer by a collector element and flip-chipped by the collector element. In some embodiments, before the picking and flip-chipping operation at act 804, the semiconductor die is lifted up from the wafer by an ejector element. FIG. 1A to FIG. 1B and FIG. 3 to FIG. 5 illustrate different views corresponding to some embodiments of act 804.

At act 806, an alignment check is performed to determine whether a misalignment is present between a center of the semiconductor die and a center of the collector element FIG. 1B and FIG. 6 illustrate different views corresponding to some embodiments of act 806.

At act 808, the semiconductor die is transferred from the collector element to a bonder element. Act 806 is performed prior to the transferring operation in act 808. In some embodiments, during the transferring operation, the misalignment is compensated if the misalignment is present between the center of the semiconductor die and the center of the collector element. The compensation may be implemented by shift and/or rotation of the bonder element. FIG. 1C to FIG. 1D and FIG. 7 to FIG. 8 illustrate different views corresponding to some embodiments of act 808.

At act 810, the semiconductor die is bonded to a carrier by the bonder element. FIG. 1E and FIG. 9 to FIG. 10 illustrate different views corresponding to some embodiments of act 810.

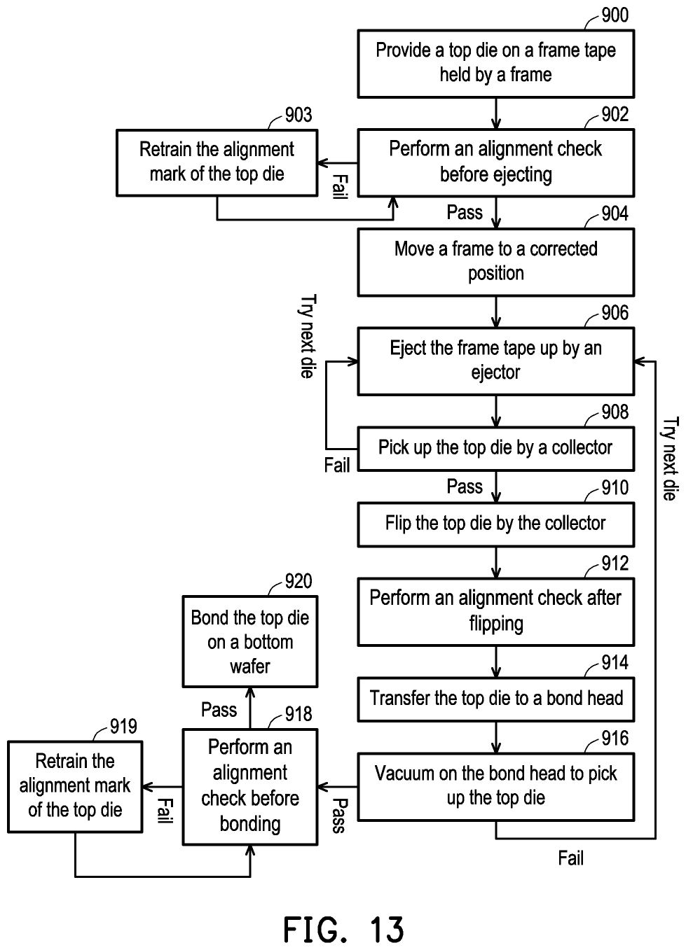

FIG. 13 illustrates a method of forming a semiconductor device in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

Act 900 is implemented to provide a top die on a frame tape held by a frame.

Act 902 is implemented to perform an alignment check before ejecting. In some embodiments, the result of the alignment check is evaluated to determine whether the result passes or fails the specification or standard. If the result passes the specification or standard, act 904 is implemented to move a frame to a corrected position. If the result fails the specification or standard, act 903 is implemented to retrain the alignment mark of the top die, and act 902 is then implemented again.

Act 906 is implemented to eject the frame tape up by an ejector.

Act 908 is implemented to pick up the top die by a collector. In some embodiments, the vacuum performance is evaluated to determine whether the vacuum passes or fails the specification or standard. If the vacuum passes the specification or standard, act 910 is implemented to flip the top die by the collector. If the vacuum fails the specification or standard, act 906 is then implemented to try next die.

Act 910 is implemented to flip the top die by the collector.

Act 912 is implemented to perform a top die alignment after flipping.

Act 914 is implemented to transfer the top die to a bond head.

Act 916 is implemented to vacuum on the bond head to pick up the top die. In some embodiments, the vacuum performance is evaluated to determine whether the vacuum passes or fails the specification or standard. If the vacuum passes the specification or standard, act 918 is implemented to perform a top die alignment before bonding. If the vacuum fails the specification or standard, act 906 is then implemented to try next die.

Act 918 is implemented to perform a top die alignment before bonding. In some embodiments, the result of the alignment check is evaluated to determine whether the result passes or fails the specification or standard. If the result passes the specification or standard, act 920 is implemented to bond the top die on a bottom wafer. If the result fails the specification or standard, act 919 is implemented to retrain the alignment mark of the top die, and act 918 is then implemented again.

In some embodiments, a flip-chip bonding apparatus includes an optical microscope (e.g., IC camera) for an alignment check before the semiconductor die is transferred to a bonder element. Such alignment check provides overlay data to compensate the die shift, so that the semiconductor die can be bonded to the bonder element accurately and therefore bonded to the carrier precisely. In some embodiments, the die-to-wafer hybrid bonding exhibits great alignment accuracy of less than about 0.2 um.

In some embodiments, a flip-chip bonding method includes following operations. A wafer is provided with multiple semiconductor dies on an adhesive film held by a frame element. A semiconductor die is lifted up from the wafer by an ejector element. The semiconductor die is picked up with a collector element. The semiconductor die is flip-chipped with the collector element. An alignment check is performed to determine a position of the semiconductor die, so as to determine a process tolerance between a center of the collector element and a center of the semiconductor die. The semiconductor die with the collector element is transferred to a location underneath a bonder element based on the process tolerance of the alignment check. The semiconductor die is picked up from the collector element by the bonder element. The semiconductor die is bonded to a carrier by the bonder element.

In some embodiments, a flip-chip bonding method includes following operations. A wafer is provided with multiple semiconductor dies. A semiconductor die is picked up from the wafer by a collector element and then flip-chipped by the collector element. The semiconductor die is transferred from the collector element to a bonder element. The method further includes, prior to the transferring operation, checking whether a misalignment is present between a center of the semiconductor die and a center of the collector element.

In some embodiments, a flip-chip bonding apparatus includes a pick-up unit. The pick-up region includes a frame element configured to hold an adhesive film adhered with a semiconductor die, an ejector element configured to lift up the semiconductor die, a first optical microscope configured to check a first position of the semiconductor die, so as to determine the process tolerance between the semiconductor die and the ejector element, a collector element dispose over the frame element and configured to pick up the semiconductor die, and a second optical microscope configured to check a second position of the semiconductor die, so as to determine the process tolerance between the semiconductor die and the collector element.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A flip-chip bonding method, comprising:
providing a wafer with multiple semiconductor dies on an adhesive film held by a frame element;
lifting a semiconductor die up from the wafer by an ejector element;
picking the semiconductor die up with a collector element;
flip-chipping the semiconductor die with the collector element;
performing an alignment check to determine a position of the semiconductor die so as to determine a process tolerance between a center of the collector element and a center of the semiconductor die;
transferring the semiconductor die with the collector element to a location underneath a bonder element based on the process tolerance of the alignment check;
picking the semiconductor die up from the collector element by the bonder element; and
bonding the semiconductor die to a carrier by the bonder element.

2. The method of claim 1, wherein the transferring process is optimized until a center of the bonder element is substantially aligned with the center of the semiconductor die.

3. The method of claim 1, wherein the alignment check comprises detection of an intensity of light reflection of an alignment mark on the semiconductor die by an optical microscope.

4. The method of claim 1, wherein the alignment check comprises detection of an edge of the semiconductor die by a camera.

5. The method of claim 1, further comprising, before lifting the semiconductor die up from the wafer by the ejector element, performing an alignment check to determine a position of the semiconductor die so as to determine a process tolerance between the center of the semiconductor die and a center of the ejector element.

6. The method of claim 5, further comprising adjusting a position of the frame element or the ejector element if the process tolerance fails the specification or standard.

7. The method of claim 5, wherein the ejector element comprises lifting pins, and lifting the semiconductor die up by the ejector element comprises moving the lifting pins upwards to push up the semiconductor die.

8. The method of claim 1, further comprising, before bonding the semiconductor die to the carrier, performing an alignment check to determine a position of the semiconductor die so as to determine a process tolerance between the center of the semiconductor die and the center of the desired region of the carrier.

9. The method of claim 8, further comprising adjusting a position of the carrier or the bonder element if the process tolerance fails the specification or standard.

10. The method of claim 1, wherein the bonder element has a curved surface.

11. A flip-chip bonding method, comprising:
providing a wafer with multiple semiconductor dies;
picking a semiconductor die up from the wafer by a collector element and flip-chipping the semiconductor die by the collector element;
transferring the semiconductor die from the collector element to a bonder element; and
before the transferring operation, determining whether a misalignment is present between a center of the semiconductor die and a center of the collector element.

12. The method of claim 11, further comprising, during the transferring operation, compensating the misalignment if the misalignment is present between the center of the semiconductor die and the center of the collector element.

13. The method of claim 11, further comprising bonding the semiconductor die to a carrier by the bonder element.

14. The method of claim 11, wherein the checking operation comprises detection of an intensity of light reflection of the alignment mark on the semiconductor die by an optical microscope.

15. The method of claim 11, wherein the checking operation comprises detection of an edge of the semiconductor die by a camera.

16. The method of claim 11, further comprising, before the picking and flip-chipping operation, lifting the semiconductor die up from the wafer by an ejector element.

17. The method of claim 11, wherein the bonder element has a curved surface.

18. A flip-chip bonding apparatus, comprising:
a pick-up unit, comprising:
a frame element configured to hold an adhesive film adhered with a semiconductor die;
an ejector element configured to lift up the semiconductor die;
a first optical microscope configured to check a first position of the semiconductor die, so as to determine a process tolerance between the semiconductor die and the ejector element;
a collector element dispose over the frame element and configured to pick up the semiconductor die; and
a second optical microscope configured to check a second position of the semiconductor die, so as to determine a process tolerance between the semiconductor die and the collector element.

19. The flip-chip bonding apparatus of claim 18, further comprising:
a bonding unit, comprising:
a stage configured to hold a carrier;
a bonding element disposed over the stage and configured to receive the semiconductor die from the collector element; and
a third optical microscope configured to check a third position of the semiconductor die, so as to determine a process tolerance between the semiconductor die and the carrier.

20. The flip-chip bonding apparatus of claim 18, wherein the bonder element has a curved surface.
